(19) United States
(12) Patent Application Publication
(10) Pub. No.: US 2008/0116552 A1
(43) Pub. Date: May 22, 2008

(54) Electronic System With Lead Free Interconnections And Method of Fabrication

(76) Inventors: James Rose, Guilderland, NY (US); Robert Lewandowski, Amsterdam, NY (US); Thomas Gorczyca, Schnectady, NY (US); Kevin Durocher, Schnectady, NY (US); Jonathan Short, Saratoga Springs, NY (US); Donna Sherman, East Greenbush, NY (US)

Correspondence Address: GENERAL ELECTRIC COMPANY;GLOBAL RESEARCH, PATENT DOCKET RM. BLDG. K1-4A59, NISKAYUNA, NY, 12309, US

(21) Appl. No.: 11/560,867

(22) Filed: Nov. 17, 2006

(51) Int. Cl. H01L 23/02

(52) U.S. Cl. 257/678

(57) ABSTRACT

An electronic system (1) having an interconnect structure (30, 45). In one embodiment a system (1) includes a first electronic device (2) with a first plurality of contact pads (15) each having a noble metal (18) formed along a first surface (19), and a second electronic device (3) with a second plurality of contact pads (29) each having a noble metal (18) formed along a first surface (19). The noble metal (18) of one of the contact pads (15) of the first device (2) is bonded to the noble metal (18) of one of the contact pads (29) of the second device (3). In one embodiment of an associated method of forming an interconnect structure (45), a first electronic device (2) is provided with a first plurality of contact pads (15) each having a noble metal (18) along a first surface (19), and a second electronic device (3) is provided with a plurality of contact pads (29) each having a noble metal (18) along a first surface (19). One or more of the contact pads (15) on the first device (2) is aligned with one or more of the contact pads (29) on the second device (3) to form pairs of pads (45) for electrical contact with one another. The first surface (19) of a contact pad (15) of the first device (2) is pressed against the first surface (19) of a contact pad (29) on the second device (3) to make contact between the two first surfaces (19).

### BACKGROUND OF THE INVENTION

1. Field of the Invention

This invention relates to high-density electronic systems and, more particularly, to methods and structures suitable for assembling such systems with lead-free connections.

2. Background Art

In recent years, the electronics industry has been phasing out lead-containing solders in order to reduce environmental and health-related concerns. Two groups of materials have been investigated as possible alternatives to lead-containing solders. One of these is the class of solders which contains tin as a primary constituent, with metals such as silver, copper, zinc, and bismuth.

A drawback of using lead-free solders is that these alloys have melting points in the range of 190 to 230 degrees C., considerably higher than the melting point of tin-lead eutectic solder (Sn/37Pb). Such a high temperature soldering process can induce significant thermal stress among dissimilar materials during manufacture, increasing potential for failures at the circuit board level.

With shrinking package dimensions, the most compact Ball Grid Array (BGA) devices have nearly the same pitch between solder bumps as integrated circuit Chip Scale Packages (CSPs). The diameters of solder balls to be formed on contact pads of electronic parts will scale accordingly. While the strength of a Sn—Ag—Cu lead-free solder bond may be sufficient for a large-diameter solder ball, the bonding strength is not necessarily sufficient at smaller dimensions.

Another alternative to a lead-containing solder is the class of Anisotropically Conductive Adhesives (ACAs). When compared to lead-free solder technology, ACAs offer several advantages, e.g., low processing temperatures; fluxless bonding (which eliminates the need for post-assembly cleaning and disposal of detergent and flux residuals); elimination of a separate underfilling step; and fine pitch capability. Despite these potential advantages, ACA joints add relatively high electrical resistance and exhibit poor interfacial bonding characteristics relative to solder joints. A high dielectric constant characteristic of ACAs is a disadvantage when designing products for high-speed applications.

### BRIEF DESCRIPTION OF THE INVENTION

In one form of the invention, an electronic system having an interconnect structure includes a first electronic device with a first plurality of contact pads each having a noble metal formed along a first surface, and a second electronic device with a second plurality of contact pads each having a noble metal formed along a first surface. The noble metal of one of the electrical contact pads of the first electronic device is bonded to the noble metal of one of the electrical contact pads of the second electronic device.

In another form of the invention, an electronic system having an interconnect structure, includes first and second electronic devices. The first electronic device includes a first plurality of conductive regions and the second electronic device includes a second plurality of conductive regions. A contact structure, extending from a first conductive region of the first device to a first conductive region of the second device, includes a first metal layer in electrical contact with the first conductive region of the first device, and a second metal layer in electrical contact with the first conductive region of the second device. A third metal layer comprising a noble metal is positioned between the first and second metal layers, providing electrical continuity between the first conductive region of the first device and the first conductive region of the second device.

In one embodiment of an associated method of forming a lead-free interconnect structure, there is provided a first electronic device with a first plurality of contact pads each comprising a noble metal along a first surface, and there is provided a second electronic device having a plurality of contact pads each comprising a noble metal along a first surface. One or more of the contact pads on the first device are aligned with one or more of the contact pads on the second device to form pairs of pads for electrical contact with one another. The first surface of a contact pad of the first device is pressed against the first surface of a contact pad on the second device to make contact between the two first surfaces.

### BRIEF DESCRIPTION OF THE DRAWINGS

The invention will be more clearly understood from the following description wherein an embodiment is illustrated, by way of example only, with reference to the accompanying drawings; in which:

FIG. 1 illustrates in cross-sectional view two components during a stage of manufacture;

FIG. 2 is a cross sectional view of the components shown in FIG. 1 after completion of an assembly step;

FIG. 3 illustrates in cross-sectional view another example of two components during a stage of manufacture;

FIG. 4 is a cross-sectional view of the components shown in FIG. 3 after completion of an assembly step;

FIG. 5 illustrates in cross-sectional view still another example of two components during a stage of manufacture;

FIG. 6 is a cross-sectional view of the components shown in FIG. 5 after completion of an assembly step;

FIG. 7 illustrates an exemplary imaging system incorporating an embodiment of the invention; and

FIG. 8 is a partial cross-sectional view of a module shown in FIG. 7.

Like reference numbers are used throughout the figures to indicate like features. Individual features in the figures may not be drawn to scale.

### DETAILED DESCRIPTION OF THE INVENTION

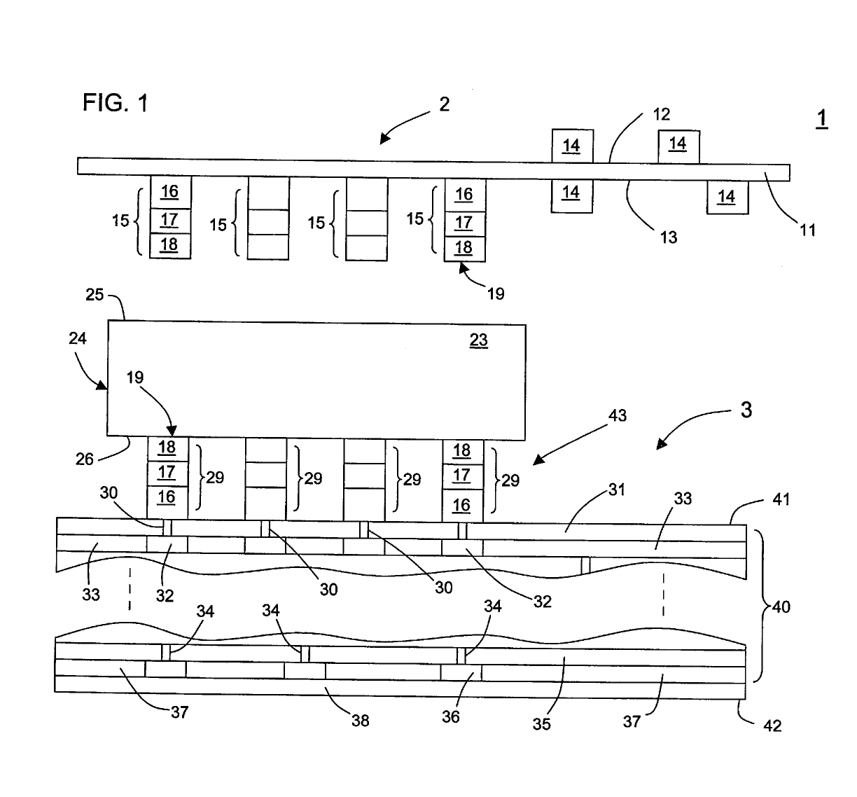

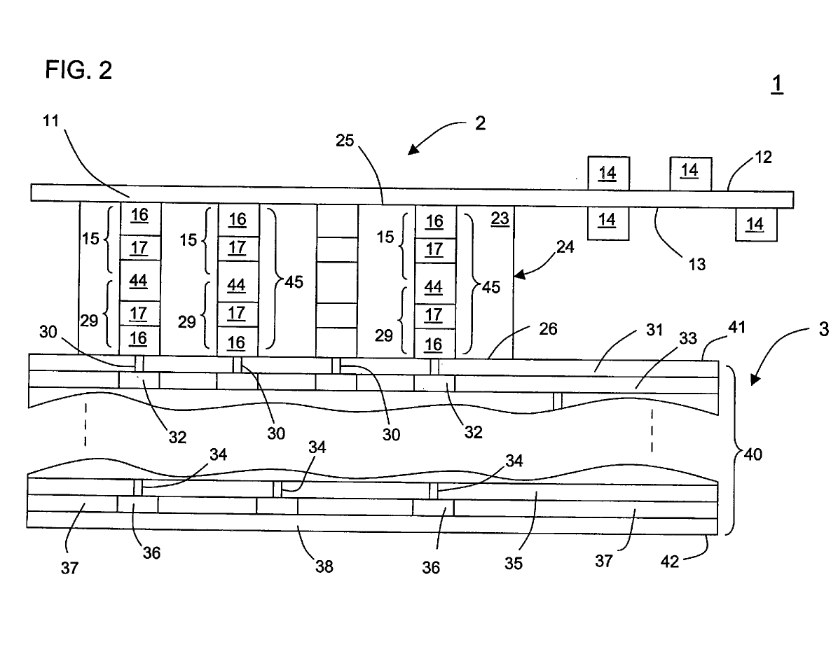

A circuit structure 1 comprising a Flexible Circuit Board (FCB) 2, a Printed Circuit Board (PCB) 3, and a sheet 24 of dielectric material 23 is shown in the partial cross sectional views of FIGS. 1 and 2, each taken along the same plane. FIG. 1 illustrates the circuit structure 1 during a step in the fabrication process prior to forming electrical connections between the illustrated components, while FIG. 2 illustrates the structure 1 after connections have been formed.

The Flexible Circuit Board (FCB) 2 includes a substrate 11 having an upper surface 12 and a lower surface 13, a plurality of electrical traces 14 formed on the upper surface 12 and the lower surface 13 of the substrate 11, and a plurality of multi-layer contact pads 15 formed on the lower surface 13 of the substrate 11. The substrate 11 may be conventionally formed of dielectric material such as, for example, a polyimide manufactured by the DuPont Corporation under the name Kapton polyimide. Other dielectric compositions may also be satisfactory, and the composition is not limited to solvent cast polyimide materials. The electrical traces 14 may be formed of copper and are shown extending in a direction orthogonal to the plane along which the view is illustrated. Protective dielectric coatings (not shown) may cover the electrical traces 14.

The Printed Circuit Board (PCB) 3, having an arbitrary number of conductor levels, N, comprises a substrate 40 having an upper surface 41 and a lower surface 42 and a plurality of multi-layer contact pads 29 formed on the upper surface 41. The partial view of the substrate 40 illustrates an upper level of vias 30 formed in an upper level dielectric layer 31, an underlying first level of inner conductors 32 formed in a first level of intra-level dielectric 33, inter-level micro-vias 34 formed in an (N-1)th level layer of intra-level dielectric 35, and an Nth level layer of intra-level dielectric 35 formed in an Nth level layer of intra-level dielectric 37. The layer of dielectric 37 is formed along a lower solder resist layer 38. The contact pads 29 formed on the upper surface 41 are connected to the first level of inner conductors 32 by the upper level vias 30.

The exemplary contact pads 15 and 29 generally comprise three layers of conductive material. A first layer 16 is formed directly on the lower surface 13 of the FCB substrate 11 or the upper surface 41 of the PCB substrate 40. The second layer 17 is formed over the first layer 16, and the third layer 18 is formed over the second layer 17 to provide a bonding surface 19. In this example, the first layer 16 is predominantly or entirely copper, and the third layer is gold. The second layer 17 may be a relatively thin diffusion barrier formed of nickel in order to limit the migration of atoms between the first and third layers. More generally, the first layer 16 may comprise any suitable conductive material, e.g., aluminum or Al/Cu or refractory metal alloys and the third layer 18 is formed of a noble metal such as gold, silver or platinum.

The copper layers 16 may be formed with any of a number of metal deposition techniques such as: electroplating, electroless plating, sputtering, evaporation, or PVD processes; followed by conventional patterning and etch steps. The layers 16 may be formed on the FCB substrate 11 to a thickness of between about 4 microns and about 20 microns and on the PCB substrate 18 to a thickness of 140 microns. The nickel layers 17 of the contact pads 15 and 29 are formed to a thickness between about 1.0 and about 1.5 microns. The gold layers 18 of the contact pads 15 and 29 are formed to a thickness between about 0.1 to about 10.0 microns. The resulting thicknesses of contact pads are 15 microns and 21 microns, respectively. The layers 17 and 18 of the contact pads 15 and 29 may be formed by sequential plating of nickel and gold using patterned photoresist as a mask. Alternatively, after the first layers 16 are patterned and etched, the layers 17 and 18 are sequentially formed by plating over the layers 16. Alternately, in a fully subtractive metal etch process, the layers 16, 17 and 18 could be sequentially formed by plating, followed by sequential pattering and etching the layers 18, 17 and 16.

An uncured dielectric adhesive 23, in the form of a semi-rigid sheet 24, having an upper surface 25 and a lower surface 26, is positioned between the FCB substrate 11 and the PCB substrate 40. The sheet 24 is composed of an adhesive material selected to have de-wetting properties with respect to the noble metal, e.g., gold, with which the third layer 18 is formed. For example, the sheet 24 may be formed of an epoxy such as that sold under the trade name TF I2202F available from TechFilm®, Billerica, Mass. Generally the dielectric adhesive 23 is of the thermosetting type, such as an epoxy, urethane, siloxane polyimide, or a blend thereof and, although so illustrated, need not be in sheet form. Suitable liquid epoxies include ERL4221, available from Dow Chemical, Midland, Mich.; and Epo-Tek 301, available from Epoxy Technology, Billerica, Mass. The sheet 24 is cut in a shape corresponding to the shape of a region 43 in which the FCB 2 and PCB 3 are to be bonded to one another. In this example, the sheet 24 is between about 25 microns and about 50 microns thick, a dimension somewhat greater than the combined thicknesses of an FCB contact pad 15 and a PCB contact pad 29.

The FCB 2 and PCB 3 are positioned in the desired alignment for mating pairs of the contact pads 15 and 29. Each pad 15 is aligned for contact of the third layer 18 thereof with the third layer 18 of a pad 29 in order to bond pairs of contact pads 15 and 29 to one another. The upper surface 25 of the adhesive sheet 24 is brought into contact with the bottom surface 13 of the FCB substrate 11 and the lower surface 26 of the adhesive sheet 24 is brought into contact with the top surface 41 of the PCB substrate 40. The assembly of the FCB 2, adhesive 23, and PCB 3 are then subjected to heat and pressure to form a bond between the third conductive layer 18 of each FCB contact pad 15 and the third conductive layer 18 of a PCB contact pad 29 brought into contact therewith. Exemplary curing conditions are in the temperature range of 50° C.-150° C. and in the pressure range of 5-25 Kg/cm². The nature and amount of energy utilized for setting the dielectric adhesive 23 is dependent upon the specific choice of adhesive. The dielectric adhesive 23 may be cured by application of any compatible form of energy, including ultraviolet radiation or RF (microwave) or convective heat. During the heating process, initially the viscosity of the adhesive 23 decreases, allowing the adhesive 23 to flow about the contact pads 15 and 29. The flowing adhesive 23 fills regions between adjacent pads. The de-wetting properties of the adhesive 23 allow mating surfaces 19 of pairs of pads 15 and 29 to come into physical contact for bonding. The electrical resistance across the contacted pairs of pads 15 and 29 created in this manner may be sufficient for a number of applications without necessitating the interdiffusion of the gold layers. Improved long-term reliability of these contacts is provided by effecting some interdiffusion of the mating surfaces 19 of pairs of pads 15 and 29. The pads 15 and 29 may subsequently be held in contact so that an inter-diffused conductive layer 44 (shown in FIG. 2) is formed by diffusion of gold atoms across the mating surfaces 19. In this example, the time required for bonding may be on the order of 1.5 to 2 hours, but with optimal selection of materials and heating techniques the process may be performed in substantially shorter time. Notably, the maximum temperature of this lead-free bonding process can be as low as the minimum temperature needed for curing the adhesive 23.

FIG. 2 illustrates the circuit structure 1 after the process of curing and bonding is complete. The structure 1 is semi-rigid, having a plurality of bonded pads 45, each comprising an FCB pad 15 and a PCB pad 29. Notably, with inter-diffusion across contact surfaces 19, the third layers 18 (shown in FIG. 1) in each pair of mating pads form one continuous layer 44 of gold in the bonded contact pads 45. An ultrasonic technique, e.g., of the type used in conventional wire bonding, may be applied to expedite gold diffusion and enhance reliability of the bonding process. The ultrasonic energy may be applied in locations along the surface 12 of the FCB 2 adjacent each bonded contact pad 45. The temperature to which the structure 1 is heated during the ultrasonic bonding process may be in the range of 25 C-50 C.

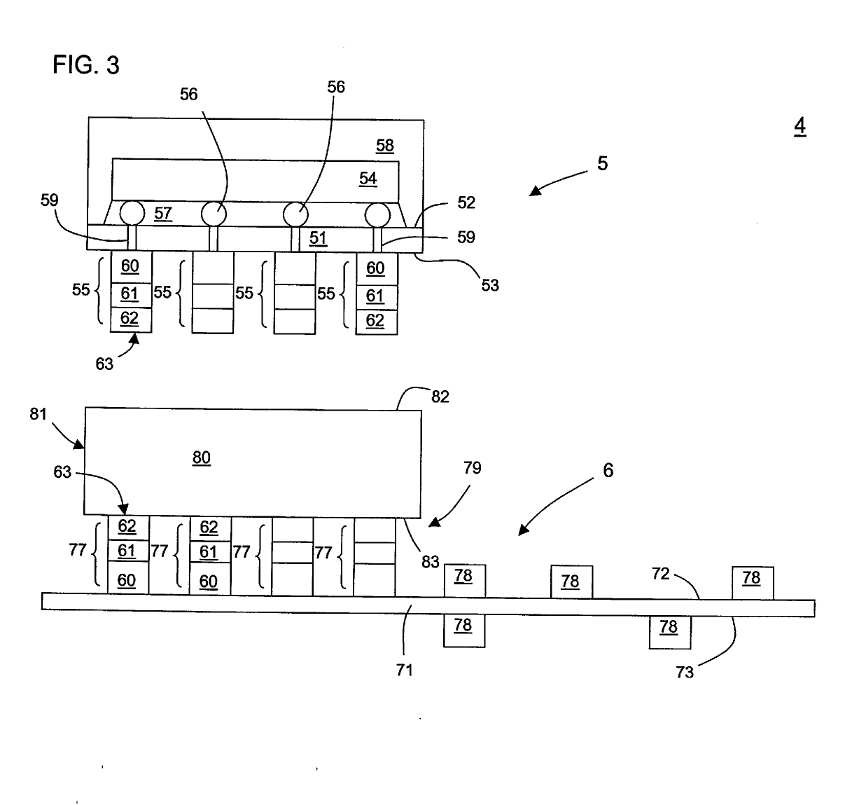

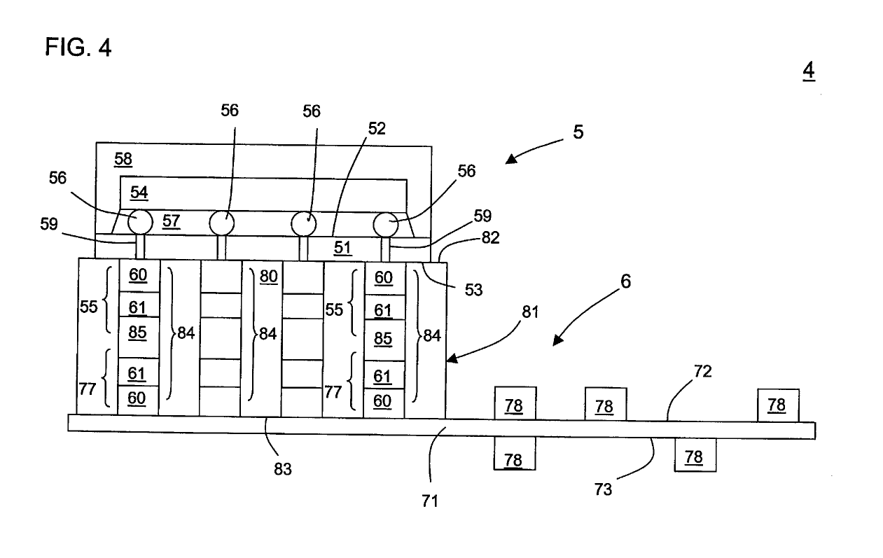

A circuit structure 4 comprising a Chip Scale Package (CSP) 5 and a Flexible Circuit Board (FCB) 6 is shown in the cross sectional views of FIGS. 3 and 4 which are each taken along the same plane. FIG. 3 illustrates the circuit structure during a step in the fabrication process prior to forming electrical connections between the illustrated components while FIG. 4 illustrates the structure 4 with the connections formed.

The CSP 5 includes a substrate 51 having an upper surface 52 and a lower surface 53, an integrated circuit die 54, and a plurality of contact pads 55 formed on the lower surface 53 of the substrate 51. By way of example, the die 54 is shown attached to the substrate 51 with a plurality of solder bumps 56. An underfill material 57, typically made of dielectric epoxy, fills regions between adjacent bumps 56. A molding compound 58 encapsulates the die 54 and the upper surface 52 of the substrate 51. Micro-vias 59 connect each of the pads 55 to a solder bump 56.

The FCB 6 includes a substrate 71 having an upper surface 72 and a lower surface 73, a plurality of electrical traces 78 formed on the upper surface 72 and the lower surface 73 of the substrate 71, and a plurality of contact pads 77 formed on the upper surface 72 of the substrate 71.

The exemplary contact pads 55 and 77 comprise three layers of conductive materials. A first layer 60 is formed directly on the lower surface 53 of the CSP substrate 51 or the upper surface 72 of the FCB substrate 71 while the second layer 61 is formed over the first layer 60, and the third layer 62 is formed over the second layer 61 to provide a bonding surface 63. In this example, the first layer 60 is predominantly or entirely copper, and the third layer 62 is gold. The second layer 61 may be a relatively thin diffusion barrier formed of nickel in order to limit the migration of atoms between the first and third layers.

The copper layer 60 may be deposited in a conventional metal deposition process as described previously. The layer 60 may be formed on the CSP substrate 51 to a thickness between about 18 and about 140 microns and on the FCB substrate 71 to a thickness between about 4 and about 20 microns. The nickel layer 61 of contact pads 55 and 77 is formed to a thickness between about 1.0 and about 1.5 microns. The gold layer 62 of contact pads 55 and 77 is formed to a thickness between about 0.1 and about 10.0 microns. The resulting thicknesses of the contact pads 55 and 77 are about 38 microns and 15 microns, respectively. The three-layer contact pads 55 and 77 may be formed by conventional processes including sequential plating of copper, nickel, and gold.

An uncured dielectric adhesive 80 is provided as a semi-rigid sheet 81 having an upper surface 82 and a lower surface 83. The adhesive material has de-wetting properties with respect to a noble metal, e.g., gold, with which the third layer 62 is formed. The sheet 81 is cut in a shape corresponding to the shape of a region 79 in which the CSP 5 and FCB 6 are bonded to one another and is placed between the CSP 5 and FCB 6. In this example, the sheet 81 is between about 50 microns and 63 microns thick, a dimension somewhat greater than the combined thicknesses of a CSP contact pad 55 and an FCB contact pad 77.

The CSP 5 and FCB 6 are positioned in alignment for mating pairs of the contact pads 55 and 77. Each pad 55 is aligned for contact of the third layer 62 thereof with the third layer 62 of a pad 77 in order to bond pairs of contact pads 55 and 77 to one another. The upper surface 82 of the adhesive sheet 81 is brought into contact with the lower surface 53 of the CSP substrate 51 and the lower surface 83 of the adhesive sheet 81 is brought into contact with the upper surface 72 of the FCB substrate 71. The assembly of the CSP 5, adhesive 80, and FCB 6 is then subjected to heat and pressure to form a bond between the third conductive layer 62 of each CSP contact pad 55 and the third conductive layer 62 of an underlying FCB contact pad 77. Exemplary curing conditions are in the range of 50 C-150 C and in the range of 5-25 Kg/cm². During the heating process, the adhesive 80 flows about the contact pads 55 and 77, filling regions between adjacent pads. Mating surfaces 63 of pairs of pads 55 and 77 make physical contact for bonding due to de-wetting properties of the adhesive 80 with respect to gold. The pads 55 and 77 may subsequently be held in contact so that an inter-diffused conductive layer 85 (shown in FIG. 4) is formed. In this example, the time required for bonding may be on the order of 1.5 to 2 hours.

FIG. 4 illustrates the structure 4 after the process of curing and bonding is complete. The structure 4 is flexible, having a plurality of bonded pads 84, each comprising a CSP pad 55 and a FCB pad 77. With inter-diffusion between mated contact surfaces 63, the third layers 62 (shown in FIG. 3) in each pair of mating pads form one continuous layer 85.

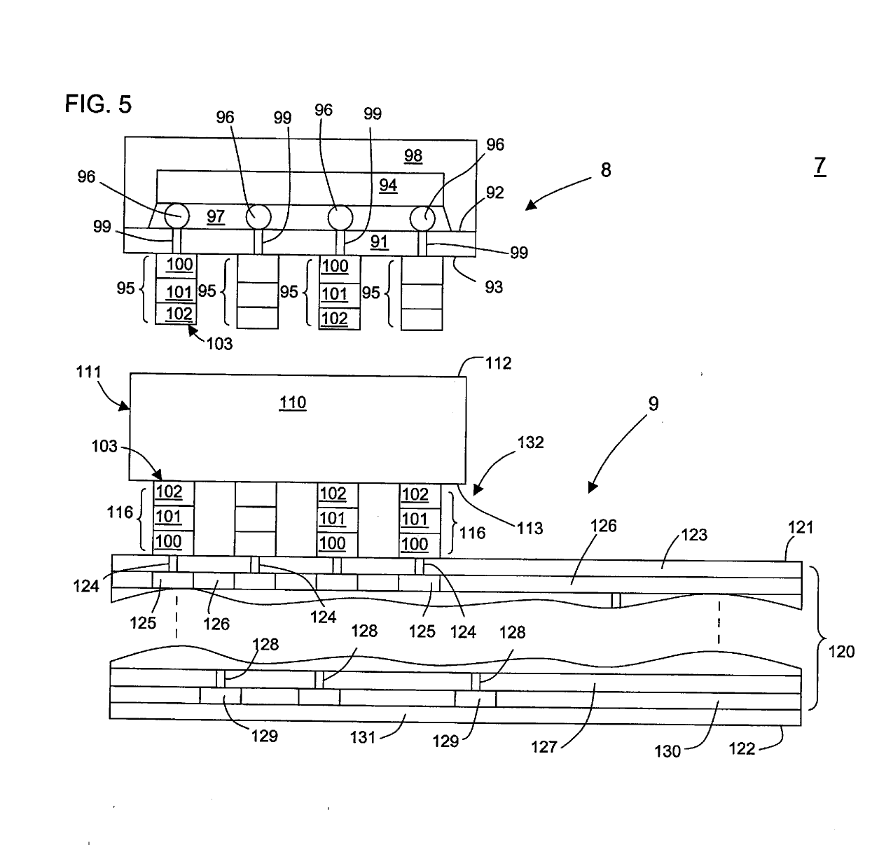

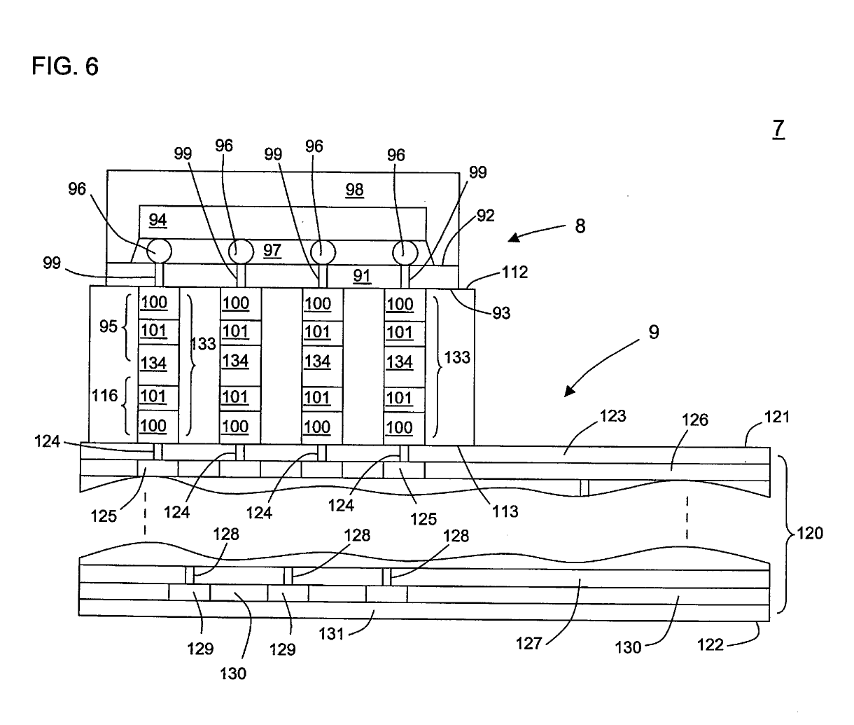

A circuit structure 7 comprising a Chip Scale Package (CSP) 8 and a Printed Circuit Board (PCB) 9 is shown in the cross sectional views of FIGS. 5 and 6, which are each taken along the same plane. FIG. 5 illustrates the circuit structure during a step in the fabrication process prior to forming electrical connections between the illustrated components and FIG. 6 shows the structure 7 after bonding is complete. The CSP 8 includes a substrate 91 having an upper surface 92 and a lower surface 93, a die 94, and a plurality of contact pads 95 formed on the lower surface 93 of the substrate 91. The die 94 is attached to the substrate with a plurality of solder bumps 96. An underfill material 97 fills regions between adjacent bumps 96. A molding compound 98 encapsulates the die 94 and the upper surface 92 of the substrate 91. Micro-vias 99 connect each of the pads 95 to a solder bump 96.

The PCB 9, having an arbitrary number of conductor levels, N, comprises a substrate 120 having an upper surface 121, a lower surface 122 and a plurality of contact pads 116 formed along these surfaces. The substrate 120 includes an upper dielectric layer 123 in which upper level vias 124 are formed, a first level of inner conductors 125 formed in a first level of intra-level dielectric 126, an (N-1)th level layer of intra-level dielectric 127 in which an Nth level of micro-vias 128 are formed, and an Nth level of inner conductors 129 formed in an Nth level intra-level dielectric 130. The Nth level intra-level dielectric 130 is formed along a lower solder resist layer 131. The contact pads 116 formed on the top surface 121 are connected to conductors 125 in the first level through the upper level of vias 124.

The exemplary contact pads 95 and 116 each comprise three layers of conductive materials. A first layer 100 is formed directly on the lower surface 93 of the CSP substrate 91 or the upper surface 121 of the FCB substrate 120. The second layer 101 is formed over the first layer 100 and the third layer 102 is formed over the second layer 101 to provide a bonding surface 103. In this example, the first layer 100 is predominantly or entirely copper, and the third layer 102 is gold. The second layer 101 may be a relatively thin diffusion barrier formed of nickel in order to limit the migration of atoms between the first and third layers.

The copper layer 100 may be deposited with an electrolytic plating process on the lower surface 93 of CSP substrate 91 to a thickness between about 18 and about 140 microns, and on the upper surface 121 of the PCB substrate 120 to a thickness between about 18 and about 140 microns. The nickel layer 101 of the contact pads 95 and 116 is formed to a thickness between about 1.0 and about 1.5 microns. The gold layer 102 of the contact pads 95 and 116 is formed to a thickness between about 0.1 and about 2.0 microns. The resulting thicknesses of contact pads 95 and 116 are 38 microns and 38 microns, respectively. The three-layer contact pads 95 and 116 may be formed by sequential plating of copper, nickel, and gold with a patterned photoresist (not shown) as a mask.

An uncured dielectric adhesive 110 is placed between the CSP 8 and FCB 9. The adhesive 110 is provided as a volume of viscous liquid adhesive 111 has an upper surface 112 and a lower surface 113. The adhesive 110 is a material having de-wetting properties with respect to the gold with which the third layer 102 is formed. The adhesive 111 is dispensed in a shape corresponding to the shape of the region 132 in which the CSP 8 and PCB 9 are bonded to one another. In this example, the adhesive 111 is between about 100 and 400 microns thick, a dimension somewhat greater than the combined thicknesses of a CSP contact pad 95 and a PCB contact pad 116. Use of a liquid adhesive may be preferred when bonding between the CSP 8 and the PCB 9 as use of a liquid, e.g., an epoxy, allows for a significant reduction in required bonding force between contact pads. This may be desirable because neither the PCB nor the CSP is as compliant as an FCB.

The CSP 8 and PCB 9 are positioned in alignment for mating pairs of the contact pads 95 and 116. Each pad 95 is aligned for contact of the third layer 102 thereof with the third layer 102 of a pad 116 in order to bond pairs of contact pads 95 and 116 to one another. The upper surface 112 of the adhesive sheet 111 is brought into contact with the lower surface 93 of the CSP substrate 91 and the lower surface 113 of the adhesive sheet 111 is brought into contact with the upper surface 121 of the PCB substrate 120. The assembly of the CSP 8, adhesive, and PCB 9 are then subjected to heat and pressure to form a bond between the third conductive layer 102 of each CSP contact pad 95 and the third conductive layer 102 of an underlying PCB contact pad 116. Exemplary curing conditions are in the range of 50 C-150 C and in the range of 1-5 Kg/cm². During the heating process, the adhesive 110 flows about the contact pads 95 and 116 and fills regions between adjacent pads. The de-wetting properties of the adhesive 110 allow mating surfaces 103 of pairs of pads 95 and 116 to make physical contact for bonding. The pads 95 and 116 may subsequently be held in contact so that an inter-diffused conductive layer 134 (shown in FIG. 6) is formed. In this example, the time required for bonding may be on the order of 1.5 to 2 hours.

FIG. 6 illustrates the structure 7 after the process of curing and bonding is complete. The structure 7 is semi-rigid, having a plurality of bonded pads 133, each comprising a CSP pad 95 and a FCB pad 116. With inter-diffusion between contact surfaces 103, the third layers 102 (shown in FIG. 5) in each pair of mating pads form one continuous layer 134 of gold in the bonded contact pads 133.

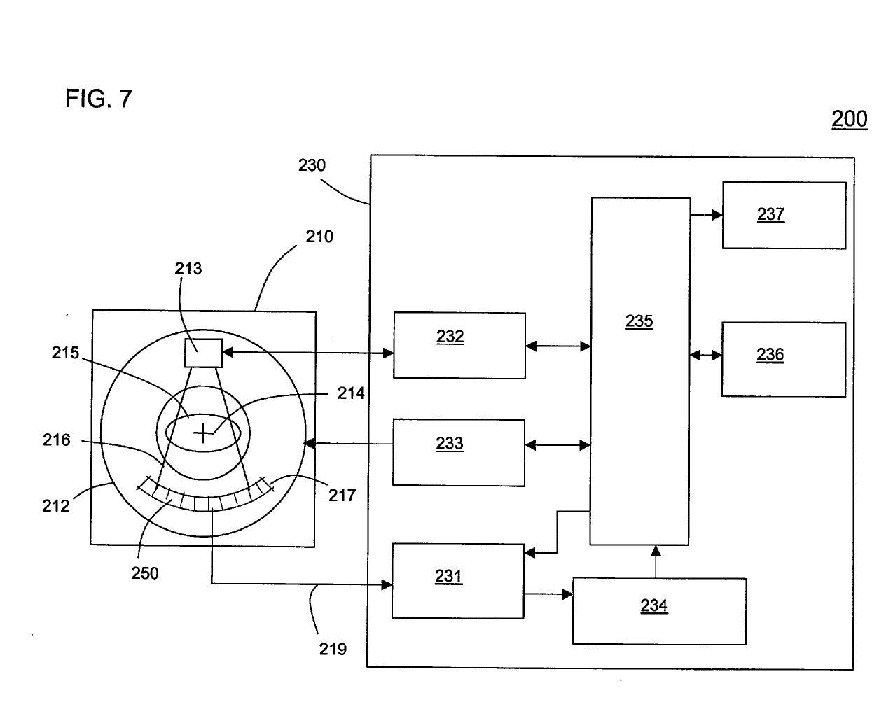

In FIG. 7, an exemplary Computed Tomography (CT) imaging system 200 including a gantry system 210 is shown in a partial cross-sectional view. The system 200 includes a console 230 which contains a computer 235, an X-ray controller 232, a gantry monitor controller 233, and a data acquisition system 231. The gantry system 210 has a rotating gantry 212 housing a source 213 that projects a beam of x-rays 216 toward a two-dimensional detector array 217 mounted on the opposite side of the gantry 212. The detector array 217 is formed with multiple rows of detector modules 250. Typically signals from the detector array 217 are sent to the data acquisition system 231 via a connection cable 219. The data acquisition system 231 samples analog data from sensors 217 through the cable 219 and converts the data to digital signals for subsequent processing. An image reconstructor 234 receives sampled and digitized x-ray data from the data acquisition system 231 and performs high-speed image reconstruction. The reconstructed image is applied as an input to the computer 235. The computer 235 also receives commands and scanning parameters from an operator via console 236. A display 237 allows the operator to observe the reconstructed image and other data from computer 235. During a scan to acquire x-ray projection data, gantry 212 and the components mounted therein rotate about a center of rotation 214. Rotation of components on the gantry 212 and operation of x-ray source 213 are governed by an x-ray controller 232 and a gantry monitor controller 233.

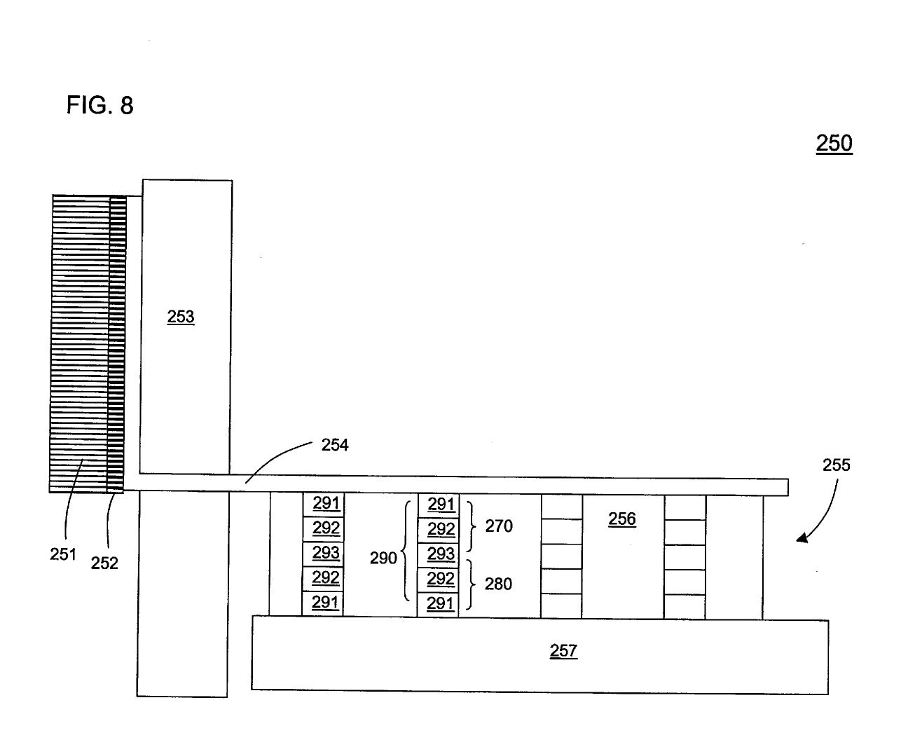

In FIG. 8 an exemplary application of an embodiment of the invention is shown. A detector module 250 includes an array of scintillators 251, a photodiode array 252, an alignment structure 253, a Flexible Circuit Board 254, a contact region 255, a dielectric adhesive 256, and a Printed Circuit Board 257. The flexible circuit board 254 is bonded to the back of the array of photodiodes 252 and extends through the alignment structure 253. The flexible circuit board 254 is bonded to the rigid PCB 257 in a contact region 255 having a plurality of bonded contact pads 290. Each pad 290 comprises a pair of pads 270 and 280. The pads 270 are formed on the flexible circuit board 254 and the pads 280 are formed on the PCB 257. The contact pads 270 and 280 comprise a first layer 291 of copper, a second layer 292 of nickel, and a third layer (not shown) of gold. The bonded contact pads 290 comprise individual pairs of the contact pads 270 and 280 which are joined along mating surfaces of their respective third gold layers (not shown) to form an interface-free contact layer 293, such as illustrated in the embodiment of FIG. 2.

Other systems incorporating embodiments of the invention include ultrasonic imaging systems. For example, in some imaging systems where rows of transducer elements are connected to flexible circuit boards or integrated devices, which are then connected to a PCB, various embodiments of the invention may be incorporated.

A feature of the described embodiments is the formation of metallurgical bonds between two electronic devices in a low temperature, lead-free environment. In contrast to conventional soldering, no flux or under filling is required. The low temperature assembly process reduces stress on interconnections, increasing system reliability. The low temperature assembly process also allows for the use of a broader range of substrate materials (having lower maximum processing temperatures) and eliminates process steps associated with solder process steps. With this flux-less bonding process there is no need for post-assembly cleaning or disposal of detergent and flux residuals. With elimination of an underfill step, reductions in manufacturing cost can be realized while improving the reliability and enabling manufacture of finer pitches. The metallurgically bonded contact pads, e.g., with a gold interface, eliminate contact resistance at the interface of pads bonded to one another, e.g., the pads 15 and 29 shown in FIG. 2. Selection of an adhesive 23 having a low dielectric constant improves the performance capability in high speed applications.

While certain embodiments and applications of the invention have been described, it will be apparent that the invention is not so limited. The invention may be applied in a wide variety of circuit systems and subassemblies. Numerous modifications, variations, substitutions and equivalents will be apparent to those skilled in the art without departing from the spirit and scope of the invention as described in the claims which follow.

1. An electronic system having an interconnect structure, comprising:
a first electronic device with a first plurality of contact pads each having a noble metal formed along a first surface thereof; and,
a second electronic device with a second plurality of contact pads each having a noble metal formed along a first surface thereof, the noble metal of one of the electrical contact pads of the first electronic device bonded to the noble metal of one of the electrical contact pads of the second electronic device with each first surface in physical contact with the other.

2. The system of claim 1 wherein the first electronic device is a circuit board and the second electronic device is a circuit board.

3. The system of claim 2 wherein the first electronic device is a flexible circuit board and the second electronic device is a printed circuit board.

4. The system of claim 1 wherein the first electronic device is a chip scale package and the second electronic device is a flexible circuit board.

5. The system of claim 1 wherein an adhesive material is provided about the contact pads of the first electronic device and the second electronic device, the adhesive being a composition taken from the group consisting of epoxy, urethane, siloxane polyimide and a blend thereof.

6. The system of claim 5 wherein the adhesive material is initially provided about the contact pads in a sheet form.

7. The system of claim 5 wherein the adhesive material is provided about the contact pads in a viscous liquid form and then cured.

8. The system of claim 1 wherein noble metal formed along the first surface of the contact pads of the first device is gold.

9. The system of claim 1 wherein the first and second devices comprise the same noble metal formed along each first surface.

10. The system of claim 1 wherein the noble metal is taken from the group consisting of gold, silver, and platinum.

11. The system of claim 1 wherein the contact pads are multi-layer contact pads having a first layer formed of copper.

12. The system of claim 11 wherein the first metal layer material of the contact pads is taken from the group consisting of copper, aluminum, Al/Cu or refractory metal alloys.

13. A method of forming a lead-free interconnect structure, comprising the steps of:
providing a first electronic device with a first plurality of contact pads each comprising a noble metal along a first surface thereof;
providing a second electronic device having a plurality of contact pads each comprising a noble metal along a first surface thereof;
aligning one or more of the contact pads on the first device with one or more of the contact pads on the second device to form pairs of pads for electrical contact with one another; and
pressing the first surface of a contact pad of the first device against the first surface of a contact pad on the second device to make contact between the two first surfaces.

14. The method of claim 13 further including the step of bonding the two first surfaces by inter-diffusion of noble metal atoms across the first surfaces.

15. The method of claim 13 wherein the step of bonding is performed by applying pressure to the two surfaces.

16. The method of claim 13 wherein the step of bonding is performed at a temperature not greater than 150° C.

17. The method of claim 13 further including the steps of applying an adhesive between the two devices and curing the adhesive under pressure and heat.

18. An electronic system having an interconnect structure, comprising:
a first electronic device with a first plurality of conductive regions formed along a surface thereof;
a second electronic device with a second plurality of conductive regions formed along a surface thereof;
a contact structure, extending from a first conductive region of the first device to a first conductive region of the second device, comprising:
a first metal layer formed of material taken from the group consisting of copper, aluminum, Al/Cu or refractory metal alloys and in electrical contact with the first conductive region of the first device;
a second metal layer formed of material taken from the group consisting of copper, aluminum, Al/Cu or refractory metal alloys and in electrical contact with the first conductive region of the second device; and
a third metal layer comprising a noble metal positioned between the first and second metal layers and providing electrical continuity between the first conductive region of the first device and the first conductive region of the second device.

19. The system of claim 18 wherein the contact structure further includes a conductive barrier layer positioned between each of the first and second metal layers and the third metal layer.

20. The system of claim 18 wherein the first and second metal layers comprise copper ands the third metal layer comprises gold and the first conductive regions are vias.
